(19) United States
(12) Patent Application Publication
(10) Pub. No.: US 2026/0043968 A1
(43) Pub. Date: Feb. 12, 2026

(54) SEMICONDUCTOR PACKAGE AND METHOD OF MANUFACTURING THE SAME

(71) Applicant: Taiwan semiconductor Manufacturing Company, Ltd., Hsinchu (TW)

(72) Inventor: Yu-Hsun LI, Yunlin County (TW)

(73) Assignee: Taiwan semiconductor Manufacturing Company, Ltd., Hsinchu (TW)

(21) Appl. No.: 19/083,683

(22) Filed: Mar. 19, 2025

Related U.S. Application Data
(60) Provisional application No. 63/680,121, filed on Aug. 7, 2024.

(51) Int. Cl. G02B 6/36; B81B 3/00; B81C 1/00; G02B 6/42

(52) U.S. Cl. CPC G02B 6/3656; B81B 3/0083; B81C 1/00317; G02B 6/4268; B81B 2201/0292; B81B 2201/037; B81B 2203/0136; B81B 2207/07; B81C 2203/035

(57) ABSTRACT

The present disclosure describes a semiconductor package with a photonic device on a micro-electro-mechanical systems (MEMS) structure. The semiconductor package includes a substrate, a MEMS structure disposed on the substrate, and a photonic device disposed on the MEMS structure. The MEMS structure includes a comb structure bonded to the substrate and a frame structure coupled to the comb structure. The photonic device is bonded to the frame structure.

### CROSS-REFERENCE TO RELATED APPLICATION

This application claims the benefit of U.S. Provisional Patent Application No. 63/680,121, titled “Silicon Photonics (SiPH) with MEMS,” filed Aug. 7, 2024, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (FinFETs), gate-all-around field effect transistors (GAAFETs), complementary field effect transistors (CFETs), nanosheet transistors, nanowire transistors, multi-bridge channel transistors, nano-ribbon transistors, and other similar structured transistors in integrated circuit (IC) chips. Additionally, multiple chips can be packaged on a substrate to improve device performance. Such scaling down has increased the complexity of manufacturing the IC chips and packaging the manufactured IC chips.

### BRIEF DESCRIPTION OF THE DRAWINGS

Aspects of the present disclosure are best understood from the following detailed description when read with the accompanying figures.

FIGS. 1-3 illustrate cross-sectional and top-down views of a semiconductor package with a photonic device on a micro-electro-mechanical systems (MEMS) structure, in accordance with some embodiments.

FIGS. 4, 5A, 5B, and 5C illustrate cross-sectional views of a semiconductor package with a laser emitter on a MEMS structure, in accordance with some embodiments.

FIG. 6 illustrates a cross-sectional view of a semiconductor package with a transmitter on a MEMS structure, in accordance with some embodiments.

FIG. 7 illustrates a cross-sectional view of a semiconductor package with a receiver on a MEMS structure, in accordance with some embodiments.

FIG. 8 illustrates a cross-sectional view of a semiconductor package with a photonic device on a MEMS structure and an interposer, in accordance with some embodiments.

FIG. 9-13 illustrates isometric views of semiconductor packages with a photonic device, a laser emitter, and an optical fiber on one or more MEMS structures, in accordance with some embodiments.

FIG. 14 illustrates a cross-sectional view of a semiconductor package with a photonic device on a MEMS structure surrounded by a cooling agent, in accordance with some embodiments.

FIG. 15 is a flow diagram of a method for fabricating a semiconductor package with a photonic device on a MEMS structure, in accordance with some embodiments.

FIGS. 16-23 illustrate cross-sectional views of a semiconductor package with a photonic device on a MEMS structure at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20 % of the value (e.g., ±1 %, ±2 %, ±3 %, ±4 %, ±5 %, ±10 %, ±20 % of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. A silicon photonic (SiPH) chip can integrate optical and electrical components on a single substrate to scale down the device dimension and improve the device performance. The optical and electrical components can be disposed on a printed circuit board (PCB) and connected to the PCB through an optional interconnect substrate, such as an interposer structure. The SiPH chip can include a transmitter and a receiver to process optical and electrical signals with high-speed interconnections. A laser emitter can generate an optical signal for modulation and optical fibers can transmit the optical signal on the SiPH chip. However, the SiPH chip can have multiple challenges. For example, the optical signal can be sensitive to vibrations, for example, from the stress in the SiPH chip, from shaking or falling, or from earthquakes. The vibrations can cause laser shifting issues and reduce the stability of the SiPH chip. Additionally, the vibrations can affect the optical signal in the optical fibers. As a result, the stability and performance of the SiPH chip can be limited by the vibrations.

Various embodiments in the present disclosure provide systems and methods for a semiconductor package with a photonic device on a micro-electro-mechanical systems (MEMS) structure. MEMS is a technology integrating miniaturized mechanical and electro-mechanical elements on an IC chip. In some embodiments, a semiconductor package can include a MEMS structure on a substrate. The MEMS structure can include a comb structure bonded to the substrate and a frame structure coupled to the comb structure. The frame structure can surround the comb structure, and the comb structure can support the frame structure with multiple connectors. The comb structure can form a capacitor between the combs bonded to the substrate and the combs coupled to the frame structure. The capacitor can control the movement of the comb structure through an electrostatic force between the combs. A photonic device can be bonded to the frame structure of the MEMS structure and suspended above the substrate. In this way, the MEMS structure can be configured to move the photonic device in a manner that compensates for the movements of the substrate and thus mitigates the vibrations of the semiconductor package. Accordingly, the stability of the photonic device can be increased and the performance of the photonic device can be improved.

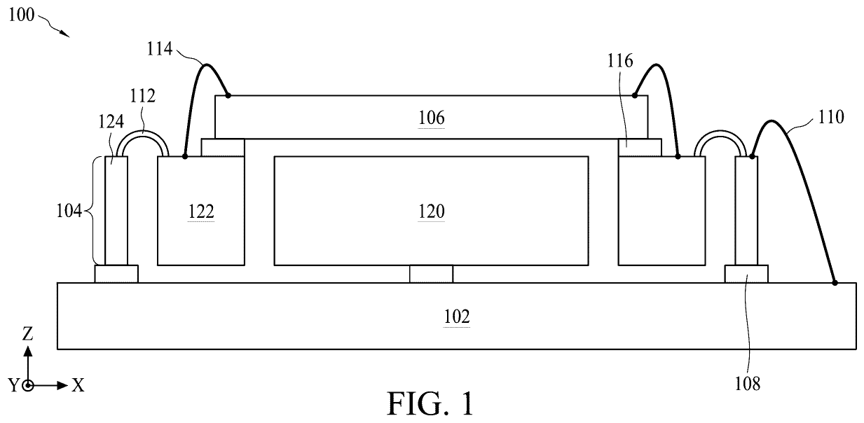

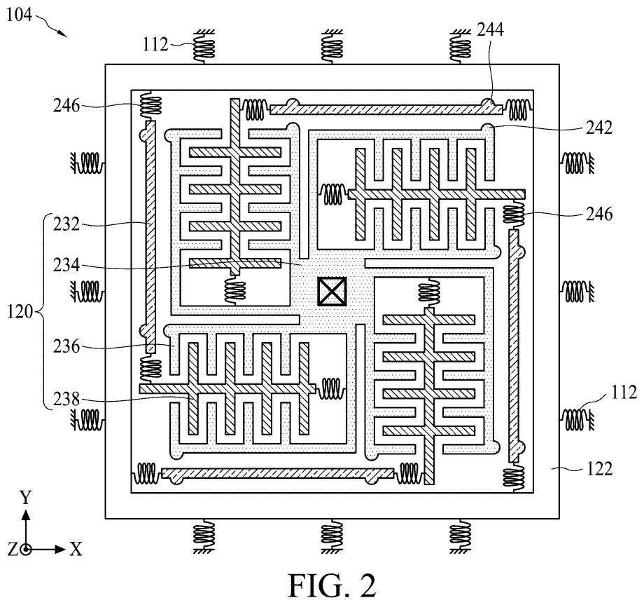

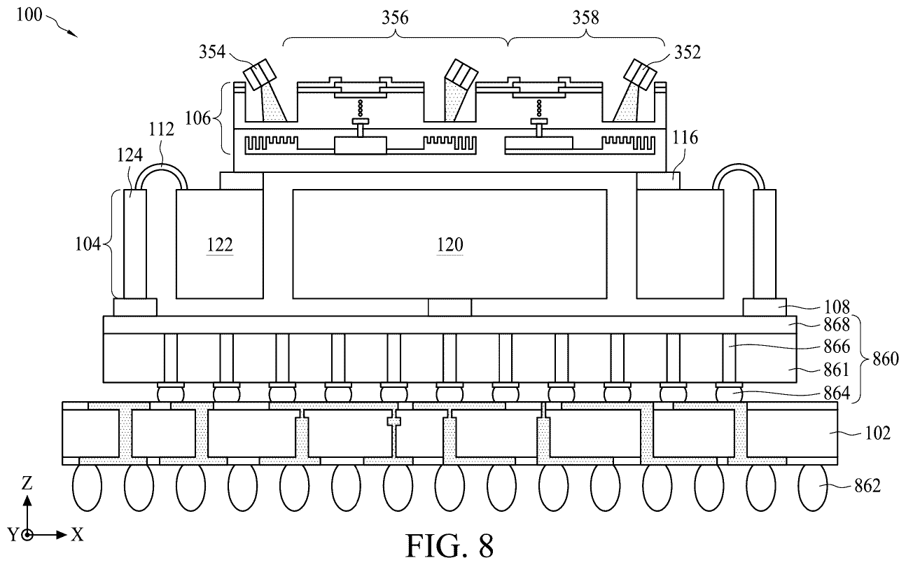

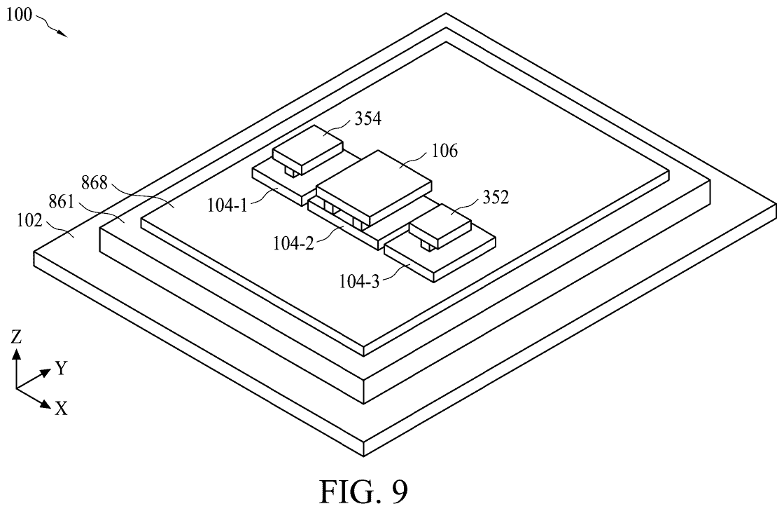

FIGS. 1, 3, 4, 6, 7, 8, and 14 illustrate cross-sectional views of various embodiments of a semiconductor package 100 with a photonic device on a MEMS structure, in accordance with some embodiments. FIG. 2 illustrates a partial top-down view of semiconductor package 100 with a photonic device on a MEMS structure, in accordance with some embodiments. FIG. 9-13 illustrates isometric views of various embodiments of semiconductor package 100 with a photonic device, a laser emitter, and an optical fiber on one or more MEMS structures, in accordance with some embodiments. In some embodiments, as shown in FIGS. 1-14, semiconductor package 100 can include a substrate 102, a MEMS structure 104, a photonic device 106, first bonding structures 108, wire bonds 110 and 114, electrical connectors 112, and second bonding structures 116. Optionally, semiconductor package 100 can include an interposer 860, as shown in FIGS. 8-13. The discussion of elements of semiconductor package 100 in FIGS. 1-14 with the same annotations applies to each other, unless mentioned otherwise. And like reference numerals generally indicate identical, functionally similar, and/or structurally similar elements.

In some embodiments, as shown in FIGS. 1, 3, 4, 6-8, and 14, MEMS structure 104 can be bonded to substrate 102 via first bonding structures 108. Photonic device 106 can be bonded to MEMS structure via second bonding structures 116. Though FIGS. 1, 3, 4, 6-8, and 14 show a single MEMS structure and a single photonic device in semiconductor package 100, semiconductor package 100 can have any number of MEMS structures and any number of photonic devices.

In some embodiments, substrate 102 can include a printed circuit board (PCB) or the like. In some embodiments, substrate 102 can include electrical connectors (shown in FIG. 8) formed on opposite sides of substrate 102. The electrical connectors on the opposite sides can be electrically inter-coupled through metal lines and vias inside substrate 102. The electrical connectors, metal lines, and metal vias on substrate 102 can electrically connect one component on one side of substrate 102 to another component on an opposite side of substrate 102. For example, substrate 102 can electrically connect photonic device 106 and MEMS structure 104 on a top side of substrate 102 through first and second bonding structures 108 and 116, wire bonds 110 and 114, and electrical connectors 112 to an external component (not shown) on the bottom side of substrate 102 through, for example, conductive bonding structures 862 as shown in FIG. 8. In some embodiments, substrate 102 can provide mechanical support for components packaged on substrate 102, such as MEMS structure 104 and photonic device 106.

In some embodiments, first bonding structures 108 can bond MEMS structure 104 to the top side of substrate 102 and second bonding structures 116 can bond photonic device 106 to MEMS structure 104. In some embodiments, each of first bonding structures 108 and second bonding structures 116 can include a conductive material, such as aluminum, copper, tungsten, tantalum nitride, solder, gold, nickel, silver, palladium, tin, and a combination thereof. In some embodiments, first bonding structures 108 can include an aluminum copper alloy. In some embodiments, first and second bonding structures 108 and 116 can include the same conductive material. In some embodiments, first and second bonding structures 108 and 116 can include different conductive materials. In some embodiments, first and second bonding structures 108 and 116 can be used to physically and electrically connect photonic device 106, MEMS structure 104, and substrate 102.

In some embodiments, MEMS structure 104 can include a comb actuator (e.g., an electrostatic comb actuator), such as a polysilicon suspended comb. In some embodiments, as shown in FIGS. 1-4, 6-8, and 14, MEMS structure 104 can include a comb structure 120, a middle frame 122, and an outer frame 124. Comb structure 120 and outer frame 124 can be bonded to substrate 102 by first bonding structures 108. Middle frame 122 can be coupled to outer frame 124 through electrical connectors 112. In some embodiments, as shown in FIG. 2, middle frame 122 can surround comb structure 120. In some embodiments, comb structure 120 can include fixed combs 236 attached to a fixed portion 234 and moving combs 238 coupled to middle frame 122 through cantilevers 232. In some embodiments, fixed combs 236 and moving combs 238 can each have multiple fingers interleaved in an alternate configuration. In some embodiments, fixed combs 236 attached to fixed portion 234 can be bonded to substrate 102 and may not move. In some embodiments, moving combs 238 can be disposed adjacent to fixed combs 236 and coupled to cantilevers 232 and fixed portion 234 through hinges 246. In some embodiments, moving combs 238 can move within a limited range between fixed combs 236. In some embodiments, middle frame 122 can move together with moving combs 238. In some embodiments, fixed portion 234 and fixed combs 236 can act as a “fixed part” of MEMS structure 104. In some embodiments, middle frame 122, moving combs 238, and cantilevers 232 can act as a “movable part” of MEMS structure 104. In some embodiments, cantilevers 232 and hinges 246 can act as transmission shafts and shock absorbers for MEMS structure 104. In some embodiments, MEMS structure 104 can further include stoppers 242 on fixed combs 236 and stoppers 244 on cantilevers 232. In some embodiments, stoppers 242 and 244 can limit the movements of cantilevers 232 and stop cantilevers 232 from crashing onto middle frame 122 during movements of MEMS structure 104. In some embodiments, MEMS structure 104 can further include a latch (not shown) to release a handle wafer for MEMS structure 104.

In some embodiments, as shown in FIGS. 1, 3, 4, 6-8, and 14, outer frame 124 can be bonded to substrate 102 through first bonding structures 108 and photonic device 106 can be bonded to middle frame 122 through second bonding structures 116. In some embodiments, first bonding structures 108 can electrically connect outer frame 124 to substrate 102. In some embodiments, middle frame 122 can act as a holder for photonic device 106. In some embodiments, electrical connectors 112 can connect each side of middle frame 122 to outer frame 124 and can support middle frame 122, as shown in FIG. 2. In some embodiments, electrical connectors 112 can electrically connect middle frame 122 and outer frame 124 and can transmit electrical signals between middle frame 122 and outer frame 124.

In some embodiments, fixed combs 236 and moving combs 238 can form a capacitor and can be electrically connected to a capacitive read-out scheme (not shown). The movements of moving combs 238 relative to fixed combs 236 can be detected by the capacitive read-out scheme. The electrostatic force between fixed combs 236 and moving combs 238 can control the movements of moving combs 238. Moving combs 238 can be configured to move during operation to compensate for the movements of substrate 102 due to any vibrations, such as shaking, falling, or earthquakes. In this way, MEMS structure 104 can support photonic device 106 with middle frame 122 and mitigate the effects of the movements of substrate 102 with the electrostatic force between fixed combs 236 and moving combs 238. As a result, photonic device 106, which can be bonded to middle frame 122 and coupled to moving combs 238 through cantilevers 232, can remain still when substrate 102 vibrates. Accordingly, MEMS structure 104 with comb structure 120 can mitigate the vibrations of photonic device 106 in semiconductor package 100 and thus improve the stability and performance of photonic device 106.

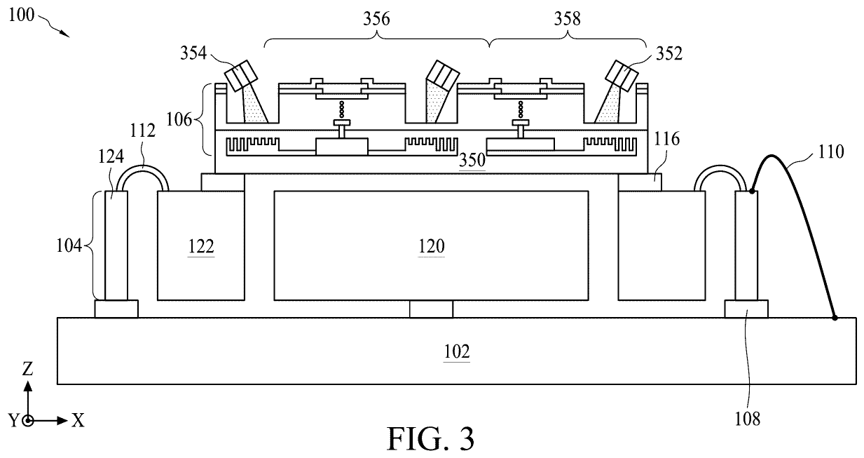

In some embodiments, photonic device 106 can include a silicon photonic chip. In some embodiments, as shown in FIG. 3, photonic device 106 can include laser emitter 354, optical fibers 352, transmitter 356, and receiver 358 on substrate 350. In some embodiments, as shown in FIGS. 9-12, laser emitter 354 and optical fibers 352 can be disposed on MEMS structure 104 separately from photonic device 106. In some embodiments, photonic device 106 can be bonded to middle frame 122 of MEMS structure 104 and suspended above comb structure 120 of MEMS structure 104. In some embodiments, optical waveguides, optical switches, optical modulators, and photodetectors can be formed on substrate 350 to transmit and receive optical signals. In some embodiments, substrate 350 can include a semiconductor material, such as silicon. In some embodiments, substrate 350 includes a crystalline silicon substrate (e.g., wafer). In some embodiments, substrate 350 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 350 can be doped depending on design requirements (e.g., p-type substrate or n-type substrate). In some embodiments, substrate 350 can be doped with p-type dopants (e.g., boron, indium, aluminum, or gallium) or n-type dopants (e.g., phosphorus or arsenic).

In some embodiments, laser emitter 354 can generate and/or modulate a laser beam (e.g., an optical signal) for photonic device 106. In some embodiments, the laser beam can be generated by laser emitter 354 based on one or more electrical signals on photonic device 106. In some embodiments, photonic device 106 can include circuits or other structures that generate electrical signals to control laser emitter 354, provide power and/or control signals to laser emitter 354, as well as detect and modify optical signals of laser emitter 354.

In some embodiments, transmitter 356 can be configured to transmit and/or modulate the optical signal based on an electrical signal. In some embodiments, transmitter 356 can transmit the optical signal through one or more optical fibers 352. In some embodiments, the optical signal can be amplified by an optical amplifier and sent to receiver 358 through optical fibers 352. In some embodiments, the optical signal can be transmitted through optical fibers 352 between transmitter 356 and receiver 358 on photonic device 106. In some embodiments, the optical signal can be transmitted between transmitter 356 and receiver 358 through optical fibers 352 between different photonic devices. In some embodiments, receiver 358 can receive the optical signal and convert the optical signal into the electrical signal with a photodetector. In some embodiments, the electrical signal can be subsequently transferred to other devices on photonic device 106.

In some embodiments, the optical signal can be transmitted through one or more optical fibers 352 on photonic device 106 as well as between photonic device 106 and other devices. In some embodiments, the electrical signal can be transferred through one or more electrical connections, such as first and second bonding structures 108 and 116, electrical connectors 112, and wire bonds 110 and 114, on photonic device 106 as well as between photonic device 106 and other devices. In some embodiments, electrical connectors 112 and wire bonds 110 and 114 can include copper, aluminum, gold, an alloy thereof, or other suitable conductive materials. Electrical connectors 112 and wire bonds 110 and 114 can be electrically and physically connected to MEMS structure 104 and photonic device 106. In some embodiments, photonic device 106 can further include circuits or other structures that generate optical and electrical signals, transmit optical and electrical signals, and/or convert optical signals to electrical signals (or vice versa) to enable communication and/or signal processing on photonic device 106.

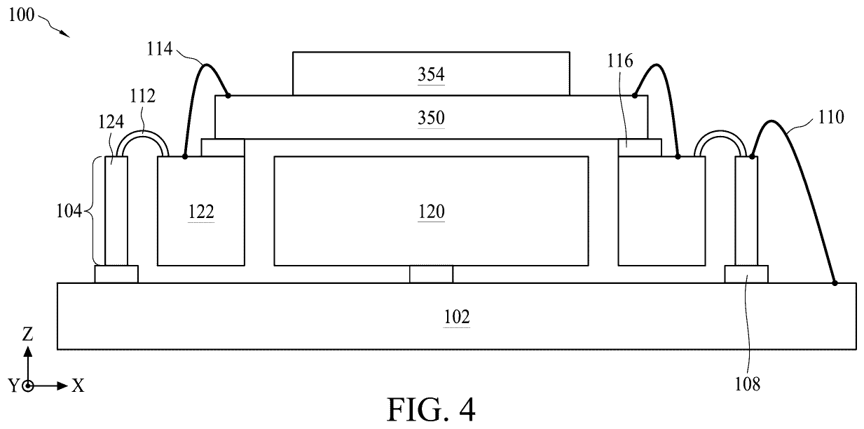

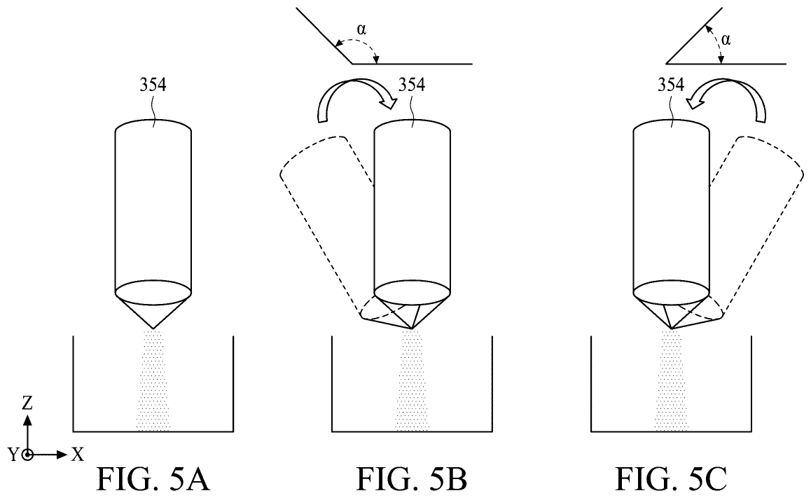

In some embodiments, laser emitter 354, transmitter 356, and receiver 358 can be integrated on a substrate 350, as shown in FIG. 3. In some embodiments, laser emitter 354, transmitter 356, and receiver 358 can be arranged separately as discrete components and individually bonded to MEMS structure 104, as shown in FIGS. 4, 6, and 7. In some embodiments, as shown in FIG. 4, laser emitter 354 can be disposed on substrate 350 and individually bonded to middle frame 122 of MEMS structure 104. In this way, MEMS structure 104 can compensate for the movements of substrate 102 and prevent laser emitter 354 from being affected by the vibrations from substrate 102. For example, as shown in FIG. 5A, laser emitter 354 can be aligned normal to substrate 350. Vibrations from substrate 102 may shift the alignment of laser emitter 354. In some embodiments, as indicated by the dotted lines in FIG. 5B, the vibrations may increase an angle α between laser emitter 354 and substrate 350 to an angle greater than about 90 degrees. In some embodiments, as indicated by the dotted lines in FIG. 5C, the vibrations may decrease angle α between laser emitter 354 and substrate 350 to an angle less than about 90 degrees. As shown in FIGS. 5A-5C, MEMS structure 104 can mitigate the vibrations from substrate 102 and realign laser emitter 354 to the position normal to substrate 350. As a result, MEMS structure 104 can mitigate the effects of the vibrations on laser emitter 354 and improve the stability and performance of laser emitter 354.

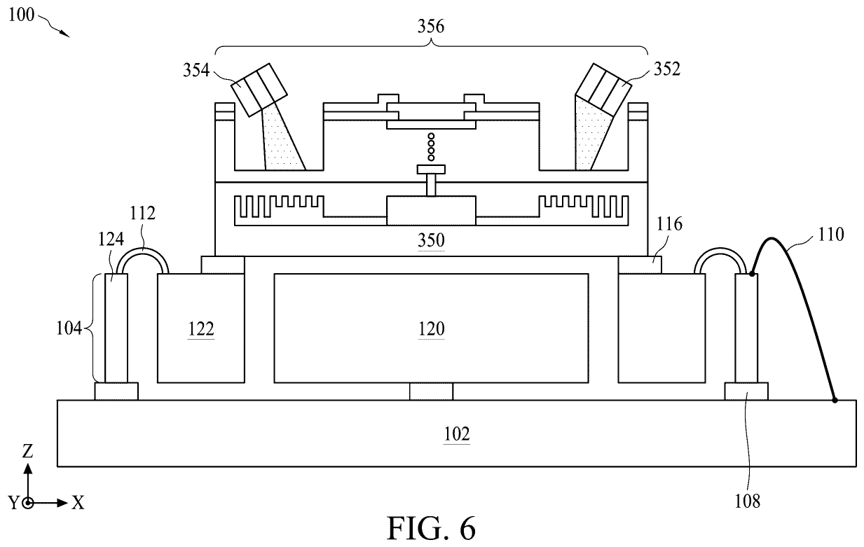

In some embodiments, as shown in FIG. 6, transmitter 356 can be disposed on substrate 350 and individually bonded to middle frame 122 of MEMS structure 104. In this way, MEMS structure 104 can compensate for the movements of substrate 102 and prevent transmitter 356 from being affected by the vibrations from substrate 102. As a result, MEMS structure 104 can mitigate the effects of the vibrations on transmitter 356 and improve the stability and performance of transmitter 356.

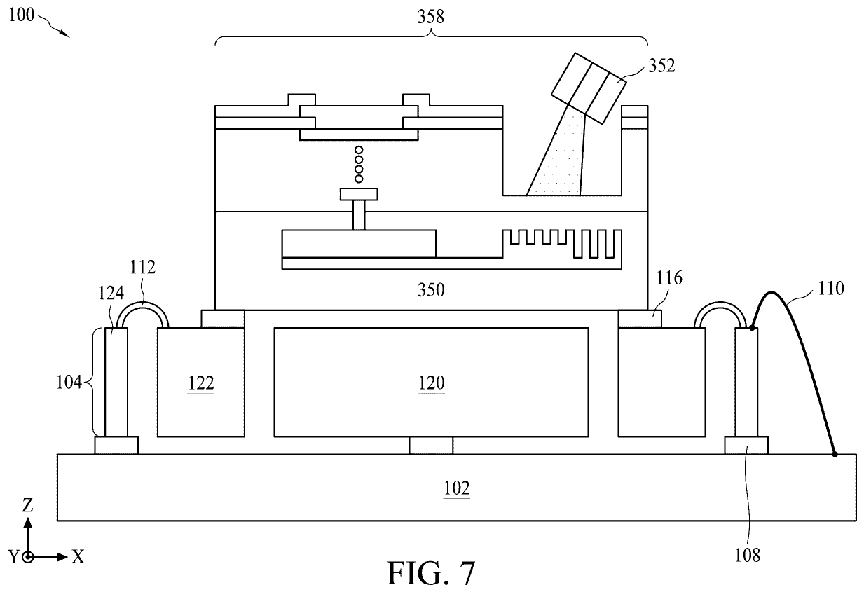

In some embodiments, as shown in FIG. 7, receiver 358 can be disposed on substrate 350 and individually bonded to middle frame 122 of MEMS structure 104. In this way, MEMS structure 104 can compensate for the movements of substrate 102 and prevent receiver 358 from being affected by the vibrations from substrate 102. As a result, MEMS structure 104 can mitigate the effects of the vibrations on receiver 358 and improve the stability and performance of receiver 358.

In some embodiments, interposer 860 can be optionally disposed between substrate 102 and MEMS structure 104. In some embodiments, interposer 860 can connect photonic device 106 and MEMS structure 104 to substrate 102. In some embodiments, interposer 860 can provide electrical connection routing, power distribution, and other suitable functions.

For example, interposer 860 can electrically connect photonic device 106 and MEMS structure 104 to substrate 102 and subsequently external components on the bottom side of substrate 102 via conductive bonding structures 862.

In some embodiments, interposer 860 can include a substrate 861, conductive bonding structures 864, conductive through-vias 866, and a redistribution layer (RDL) 868. In some embodiments, substrate 861 can include a silicon substrate. In some embodiments, conductive bonding structures 864 can electrically connect interposer 860 to substrate 102. In some embodiments, conductive bonding structures 864 can include solder bumps, copper pillars, or micro bumps. In some embodiments, RDL 868 can include interconnect structures disposed in a dielectric layer. In some embodiments, conductive through-vias 866 can include a metal (such as copper and aluminum), a metal alloy (such as copper alloy and aluminum alloy), or a combination thereof.

In some embodiments, interposer 860 can be disposed on a top surface of substrate 102 and conductive bonding structures 862 can be disposed on a bottom surface of substrate 102. In some embodiments, conductive bonding structures 862 can include ball grid array (BGA) connectors, solder bumps, metal pillars, controlled collapse chip connection (C4) bumps, micro bumps, or other suitable conductive connectors. In some embodiments, conductive bonding structures 862 can include a conductive material, such as solder, copper, aluminum, gold, nickel, silver, palladium, tin, and a combination thereof. In some embodiments, conductive bonding structures 862 can include a solder-free conductive material. In some embodiments, conductive bonding structures 862 can be used to physically and electrically connect substrate 102 to other external devices, packages, connecting components, and the like. In some embodiments, interposer 860, substrate 102, and conductive bonding structures 862 can route and transmit electrical signals between photonic device 106 and other external devices.

FIG. 9-13 illustrates isometric views of various embodiments of semiconductor package 100 with photonic device 106, laser emitter 354, and optical fibers 352 on one or more MEMS structures 104, in accordance with some embodiments. In some embodiments, photonic device 106, laser emitter 354, and optical fibers 352 can be individually bonded to respective MEMS structures, For example, as shown in FIG. 9, laser emitter 354 can be bonded to MEMS structure 104-1, photonic device 106 can be bonded to MEMS structure 104-2, and optical fibers 352 can be bonded to MEMS structure 104-3. In this way, each of MEMS structures 104-1, 104-2, and 104-3 can individually mitigate the effects of the vibrations on photonic device 106, laser emitter 354, and optical fibers 352 and improve the stability and performance of photonic device 106, laser emitter 354, and optical fibers 352. Additionally, with MEMS structures 104-1, 104-2, and 104-3, the stability and performance of photonic device 106, laser emitter 354, and optical fibers 352 may not be affected by each other. However, the manufacturing cost may increase by bonding each of photonic device 106, laser emitter 354, and optical fibers 352 to MEMS structure 104.

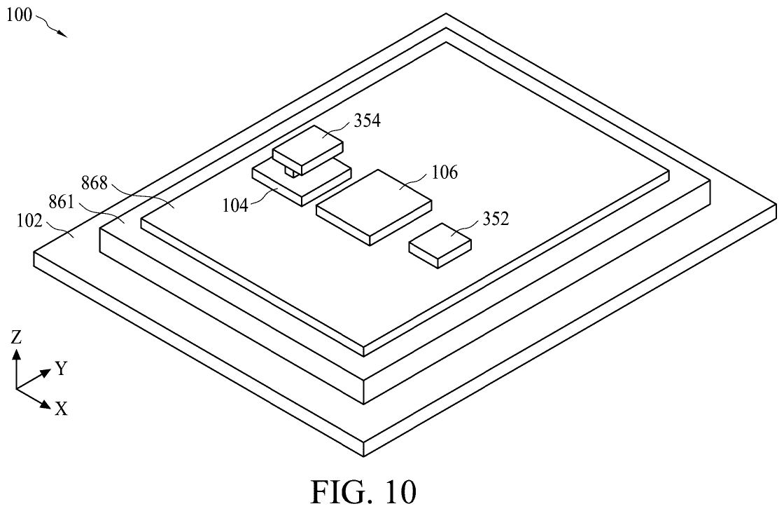

In some embodiments, as shown in FIG. 10, laser emitter 354 can be bonded to MEMS structure 104, while photonic device 106 and optical fibers 352 can be directly disposed on RDL 868 of interposer 860. In this way, MEMS structure 104 can mitigate the effects of the vibrations on laser emitter 354 and improve the stability and performance of laser emitter 354. The manufacturing cost may decrease by bonding laser emitter 354 to MEMS structure 104, while the stability and performance of optical fibers 352 and photonic device 106 may not be improved.

Similarly, in some embodiments, photonic device 106 can be bonded to MEMS structure 104, while laser emitter 354 and optical fibers 352 can be directly disposed on RDL 868 of interposer 860 (not shown). In this way, MEMS structure 104 can mitigate the effects of the vibrations on photonic device 106 and improve the stability and performance of photonic device 106. The manufacturing cost may decrease by bonding photonic device 106 to MEMS structure 104, while the stability and performance of optical fibers 352 and laser emitter 354 may not be improved.

Similarly, in some embodiments, optical fibers 352 can be bonded to MEMS structure 104, while laser emitter 354 and photonic device 106 can be directly disposed on RDL 868 of interposer 860 (not shown). In this way, MEMS structure 104 can mitigate the effects of the vibrations on optical fibers 352 and improve the stability and performance of optical fibers 352. The manufacturing cost may decrease by bonding optical fibers 352 to MEMS structure 104, while the stability and performance of photonic device 106 and laser emitter 354 may not be improved.

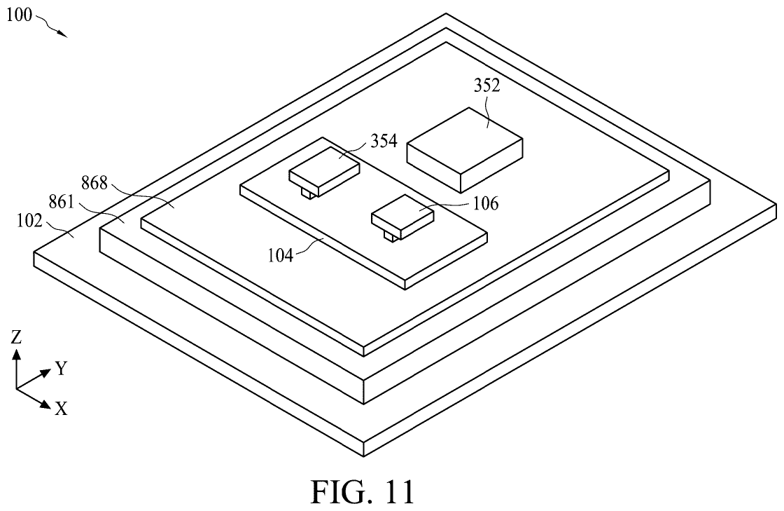

In some embodiments, as shown in FIG. 11, laser emitter 354 and photonic device 106 can be bonded to MEMS structure 104, while optical fibers 352 can be directly disposed on RDL 868 of interposer 860. In this way, MEMS structure 104 can mitigate the effects of the vibrations on laser emitter 354 and photonic device 106 and improve the stability and performance of laser emitter 354 and photonic device 106. The manufacturing cost may decrease by bonding laser emitter 354 and photonic device 106 to MEMS structure 104, while the stability and performance of optical fibers 352 may not be improved.

Similarly, in some embodiments, optical fibers 352 and photonic device 106 can be bonded to MEMS structure 104, while laser emitter 354 can be directly disposed on RDL 868 of interposer 860 (not shown). In this way, MEMS structure 104 can mitigate the effects of the vibrations on optical fibers 352 and photonic device 106 and improve the stability and performance of optical fibers 352 and photonic device 106. The manufacturing cost may decrease by bonding optical fibers 352 and photonic device 106 to MEMS structure 104, while the stability and performance of laser emitter 354 may not be improved.

Similarly, in some embodiments, optical fibers 352 and laser emitter 354 can be bonded to MEMS structure 104, while photonic device 106 can be directly disposed on RDL 868 of interposer 860 (not shown). In this way, MEMS structure 104 can mitigate the effects of the vibrations on optical fibers 352 and laser emitter 354 and improve the stability and performance of optical fibers 352 and laser emitter 354. The manufacturing cost may decrease by bonding optical fibers 352 and laser emitter 354 to MEMS structure 104, while the stability and performance of photonic device 106 may not be improved.

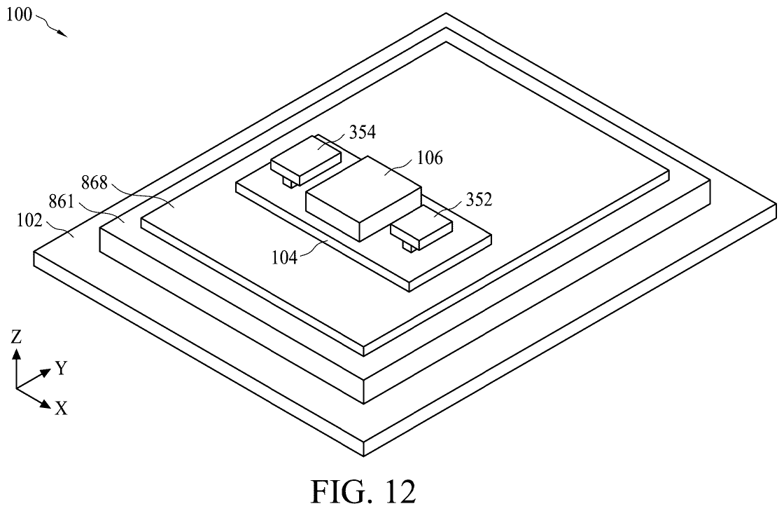

In some embodiments, as shown in FIG. 12, photonic device 106, laser emitter 354, and optical fibers 352 can be bonded to MEMS structure 104. In this way, MEMS structure 104 can mitigate the effects of the vibrations on photonic device 106, laser emitter 354, and optical fibers 352 and improve the stability and performance of photonic device 106, laser emitter 354, and optical fibers 352. Additionally, the manufacturing cost may decrease by bonding photonic device 106, laser emitter 354, and optical fibers 352 to MEMS structure 104.

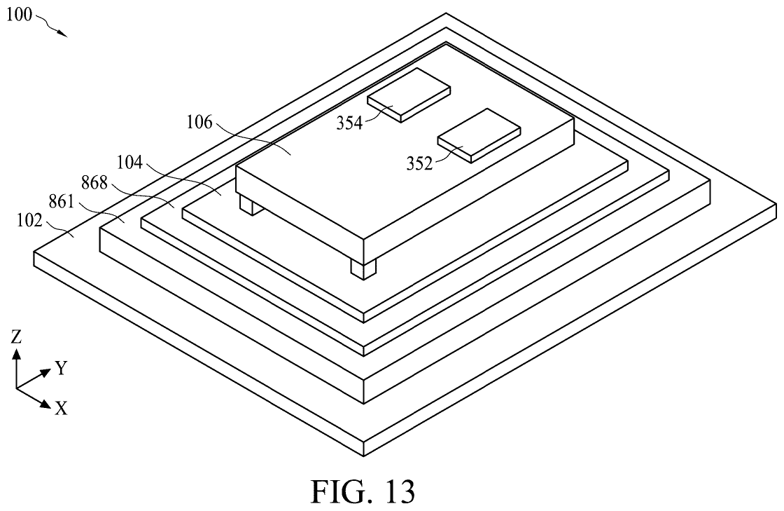

In some embodiments, as shown in FIG. 13, photonic device 106 can be bonded to MEMS structure 104, and laser emitter 354 and optical fibers 352 can be disposed on photonic device 106. In this way, MEMS structure 104 can mitigate the effects of the vibrations on photonic device 106, laser emitter 354, and optical fibers 352 and improve the stability and performance of photonic device 106, laser emitter 354, and optical fibers 352. Additionally, the manufacturing cost may decrease and the bonding process may be simplified by bonding photonic device 106 to MEMS structure 104.

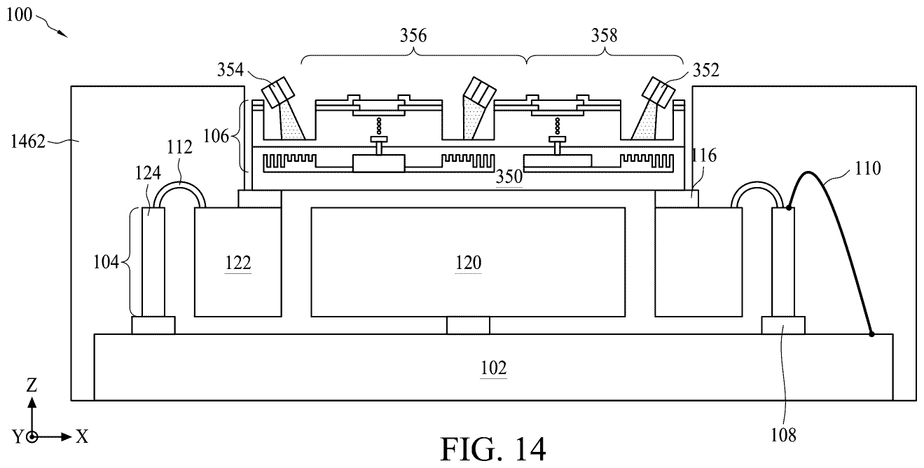

In some embodiments, FIG. 14 illustrates a cross-sectional view of semiconductor package 100 with photonic device 106 on MEMS structure 104 surrounded by a cooling agent 1462. In some embodiments, cooling agent 1462 can surround substrate 102, MEMS structure 104, and photonic device 106. In some embodiments, cooling agent 1462 can surround at least a portion of semiconductor package 100, such as photonic device 106. In some embodiments, cooling agent 1462 can improve heat dissipation of semiconductor package 100. In some embodiments, cooling agent 1462 can include cooling water or another suitable cooling agent.

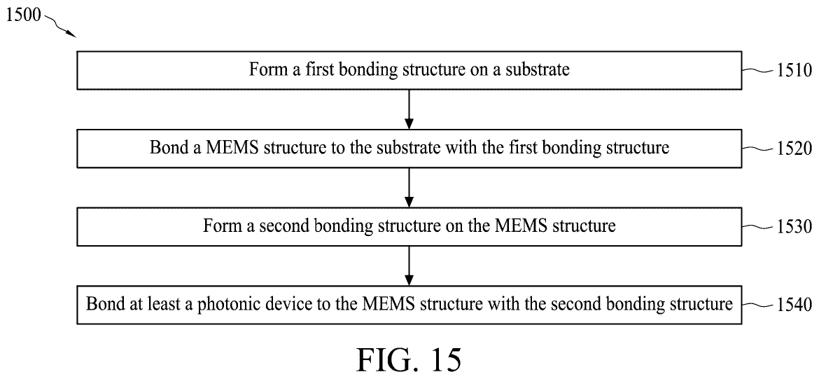

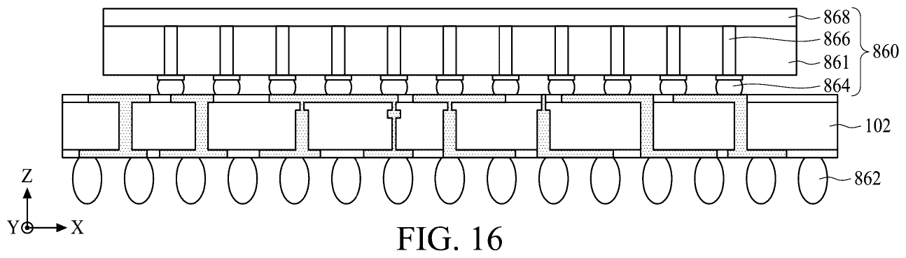

FIG. 15 is a flow diagram of a method 1500 for fabricating semiconductor package 100 with a photonic device on a MEMS structure, in accordance with some embodiments. Method 1500 may not be limited to semiconductor package 100 and can be applicable to other photonic devices that would benefit from the vibration mitigation by the MEMS structure. Additional operations may be performed between various operations of method 1500 and may be omitted merely for clarity and ease of description. Additional operations can be provided before, during, and/or after method 1500; one or more of these additional operations are briefly described herein. Moreover, not all operations may be needed to perform the disclosure provided herein. Additionally, some of the operations may be performed simultaneously or in a different order than shown in FIG. 15. In some embodiments, one or more other operations may be performed in addition to or in place of the presently-described operations. For illustrative purposes, the operations illustrated in FIG. 15 will be described with reference to the example embodiments as illustrated in FIGS. 16-23.

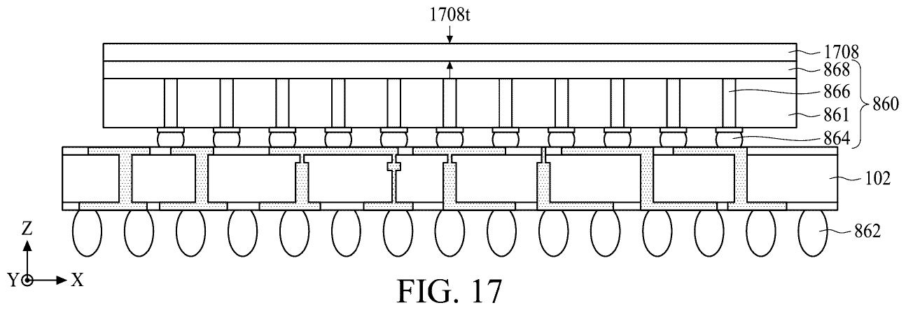

In referring to FIG. 15, method 1500 begins with operation 1510 and the process of forming a first bonding structure on a substrate. For example, as shown in FIGS. 16-20, first bonding structures 108 can be formed on interposer 860 and substrate 102. In some embodiments, as shown in FIGS. 16-18 and 20, the formation of first bonding structures 108 can include deposition of a layer of conductive adhesive material and patterning the layer of conductive adhesive material. As shown in FIGS. 16 and 17, interposer 860 can be optionally formed on substrate 102. A layer of conductive adhesive material 1708 can be blanket deposited on optional interposer 860 or substrate 102. In some embodiments, conductive adhesive material 1708 can include aluminum, copper, tungsten, tantalum nitride, solder, gold, nickel, silver, palladium, tin, and a combination thereof. In some embodiments, conductive adhesive material 1708 can include multiple layers, such as a glue layer having tantalum nitride and a layer of aluminum copper on the glue layer. In some embodiments, the layer of conductive adhesive material 1708 can have a thickness 1708t ranging from about 300 nm to about 1000 nm.

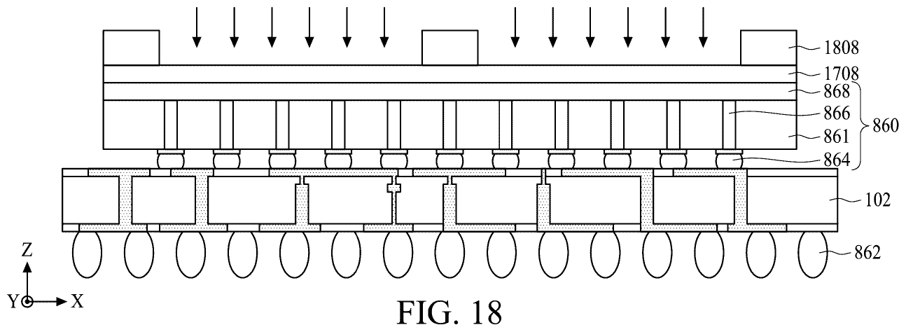

The blanket deposition of conductive adhesive material 1708 can be followed by the formation of a patterning layer 1808 on the layer of conductive adhesive material 1708, as shown in FIG. 18. In some embodiments, the formation of patterning layer 1808 can include blanket deposition of a photoresist on the layer of conductive adhesive material 1708 and a patterning process to remove a portion of the photoresist. In some embodiments, the remaining photoresist on conductive adhesive material 1708 can form patterning layer 1808.

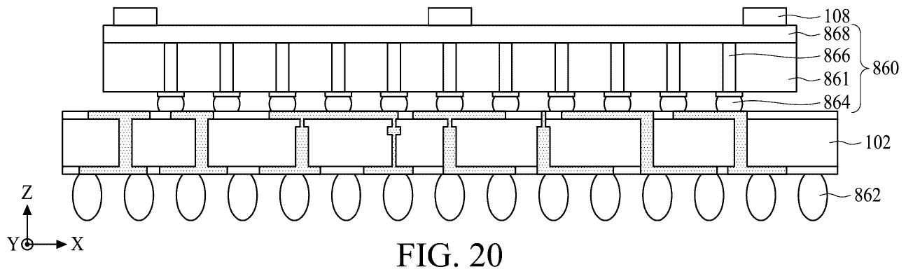

In some embodiments, an etching process can follow the formation of patterning layer 1808 to pattern the layer of conductive adhesive material 1708. In some embodiments, the layer of conductive adhesive material 1708 not covered by patterning layer 1808 can be removed by the etching process. In some embodiments, the etching process can include a dry etching process or a wet etching process. After the etching process, patterning layer 1808 can be removed and the remaining conductive adhesive material 1708 can form first bonding structures 108, as shown in FIG. 20.

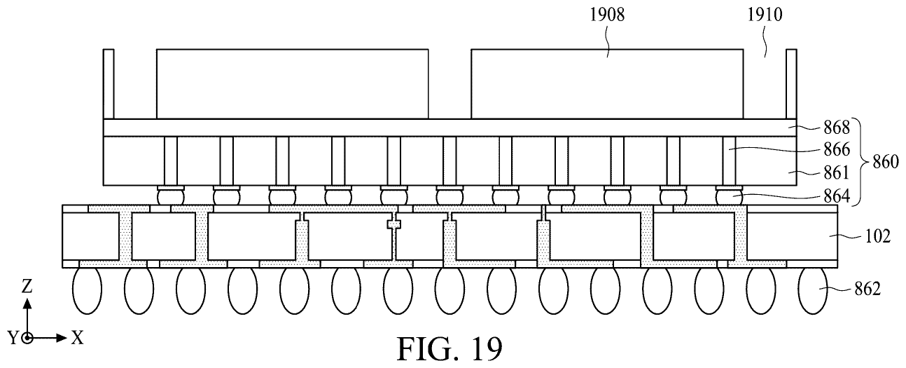

In some embodiments, as shown in FIGS. 16, 19, and 20, the formation of first bonding structures 108 can include formation of a patterning layer 1908 and deposition of first bonding structures 108. As shown in FIG. 19, patterning layer 1908 can be formed on optional interposer 860 or substrate 102. The formation of patterning layer 1908 can include blanket deposition of a photoresist on interposer 860 and a patterning process to form openings 1910 on the photoresist and expose a portion of interposer 860 or substrate 102. After the formation of patterning layer 1908, conductive adhesive material can be blanket deposited in openings 1910 and on patterning layer 1908. The deposition of conductive adhesive material can be followed by a chemical mechanical polishing process to remove the conductive adhesive material on patterning layer 1908 and an etching process to remove patterning layer 1908 and form first bonding structures 108, as shown in FIG. 20.

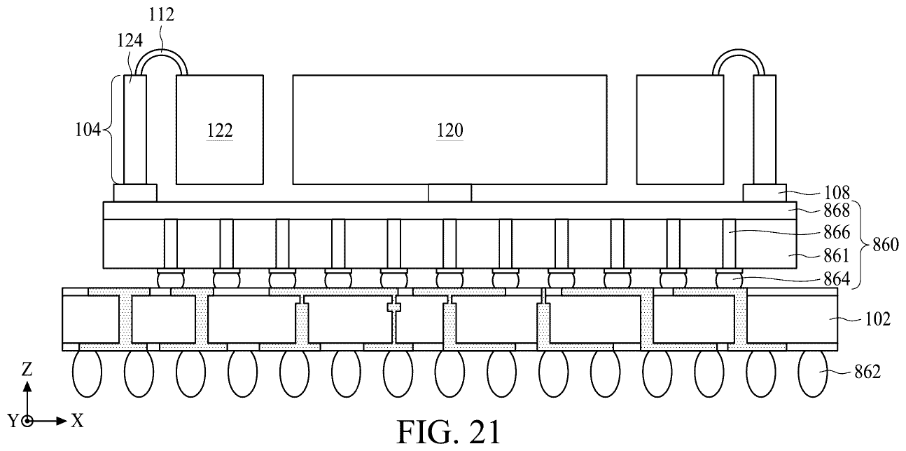

Referring to FIG. 15, in operation 1520, a MEMS structure is bonded to the substrate with the first bonding structure. For example, as shown in FIG. 21, MEMS structure 104 can be bonded to optional interposer 860 or substrate 102 with first bonding structures 108. In some embodiments, outer frame 124 and comb structure 120 of MEMS structure 104 can be positioned on first bonding structures 108 and bonded to interposer 860 or substrate 102. In some embodiments, middle frame 122 of MEMS structure 104 can be suspended above substrate 102 and supported by outer frame 124 via electrical connectors 112. In some embodiments, MEMS structure 104 can be bonded to interposer 860 or substrate 102 by an annealing process. In some embodiments, the annealing process can be performed at a temperature ranging from about 300° C. to about 1000° C. for a conductive adhesive material including aluminum copper. In some embodiments, the annealing process can be performed at a temperature ranging from about 2500° C. to about 3500° C. for a conductive adhesive material including tungsten. In some embodiments, the annealing can melt the conductive adhesive material and bond MEMS structure 104 to interposer 860 or substrate 102.

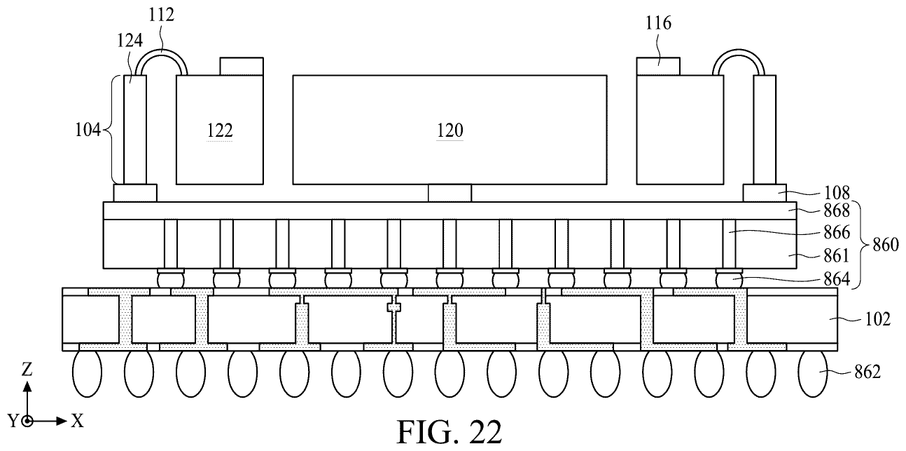

Referring to FIG. 15, in operation 1530, a second bonding structure is formed on the MEMS structure. For example, as shown in FIG. 22, second bonding structures 116 can be formed on MEMS structure 104. In some embodiments, second bonding structures 116 can be formed on middle frame 122 of MEMS structure 104. In some embodiments, second bonding structures 116 can be formed using the method of forming first bonding structures 108 as described in operation 1510. In some embodiments, second bonding structures 116 can include a conductive adhesive material, such as aluminum, copper, tungsten, tantalum nitride, solder, gold, nickel, silver, palladium, tin, and a combination thereof. In some embodiments, second bonding structures 116 can include multiple layers, such as a glue layer having tantalum nitride and a layer of aluminum copper on the glue layer. In some embodiments, first bonding structures 108 and second bonding structures 116 can include the same conductive adhesive material. In some embodiments, first bonding structures 108 and second bonding structures 116 can include different conductive adhesive materials. In some embodiments, second bonding structures 116 can have a thickness ranging from about 300 nm to about 1000 nm.

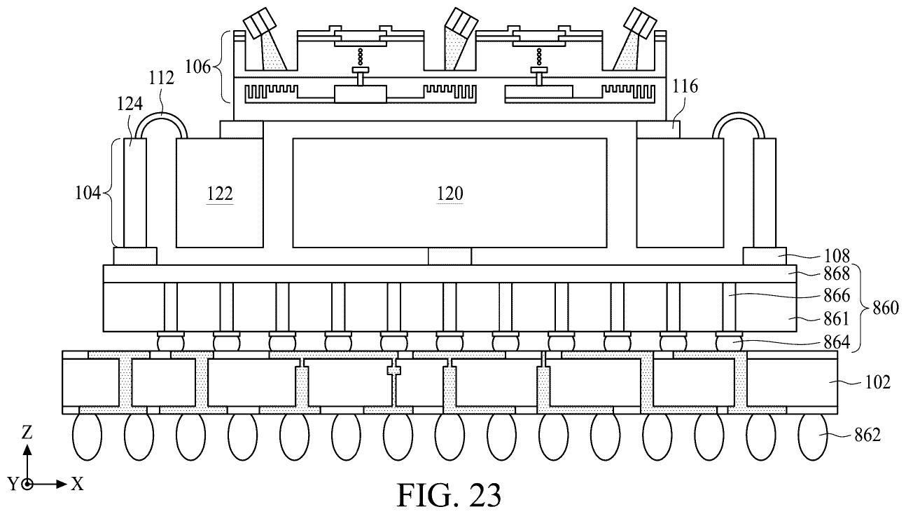

Referring to FIG. 15, in operation 1540, at least a photonic device is bonded to the MEMS structure with the second bonding structure. For example, as shown in FIG. 23, photonic device 106 can be bonded to MEMS structure 104 with second bonding structures 116. In some embodiments, photonic device 106 can be positioned on second bonding structures 116 and bonded to middle frame 122 of MEMS structure 104 by an annealing process as described in operation 1520. In some embodiments, the annealing process can be performed at a temperature ranging from about 300° C. to about 1000° C. for a conductive adhesive material including aluminum copper. In some embodiments, the annealing process can be performed at a temperature ranging from about 2500° C. to about 3500° C. for a conductive adhesive material including tungsten. In some embodiments, the annealing can melt the conductive adhesive material in second bonding structures 116 and bond photonic device 106 to middle frame 122 of MEMS structure 104. With MEMS structure 104, photonic device 106 can be suspended above substrate 102 and the effects of the movements of substrate 102 can be compensated by the electrostatic force between fixed combs 236 and moving combs 238, as shown in FIG. 2. As a result, photonic device 106, which can be bonded to middle frame 122 and coupled to moving combs 238 through cantilevers 232, can remain still when substrate 102 vibrates. Accordingly, MEMS structure 104 with comb structure 120 can mitigate the vibrations of photonic device 106 in semiconductor package 100 and thus improve the stability and performance of photonic device 106.

Various embodiments in the present disclosure provide systems and methods for semiconductor package 100 with photonic device 106 on MEMS structure 104. In some embodiments, semiconductor package 100 can include MEMS structure 104 on substrate 102.

MEMS structure 104 can include comb structure 120 bonded to substrate 102 and middle frame 122 coupled to comb structure 120. Middle frame 122 can surround comb structure 120 and comb structure 120 can support middle frame 122 with multiple hinges 246 and cantilevers 232. Comb structure 120 can form a capacitor between fixed combs 236 bonded to substrate 102 and moving combs 238 coupled to middle frame 122. The capacitor can control the movement of comb structure 120 through an electrostatic force between fixed combs 236 and moving combs 238. Photonic device 106 can be bonded to middle frame 122 of MEMS structure 104 and suspended above substrate 102. In this way, MEMS structure 104 can be configured to move photonic device 106 in a manner that compensates for the movements of substrate 102 and thus mitigates the vibrations from substrate 102. Accordingly, the stability of photonic device 106 can be increased and the performance of photonic device 106 can be improved.

In some embodiments, a semiconductor package includes a substrate, a micro-electro-mechanical systems (MEMS) structure disposed on the substrate, and a photonic device disposed on the MEMS structure. The MEMS structure includes a comb structure bonded to the substrate and a frame structure coupled to the comb structure. The photonic device is bonded to the frame structure.

In some embodiments, a semiconductor structure includes a substrate and a micro-electro-mechanical systems (MEMS) structure disposed on the substrate. The MEMS structure includes a fixed part bonded to the substrate, and a movable part surrounding the fixed part and supported by the fixed part. The semiconductor structure further includes a photonic structure bonded to the movable part of the MEMS structure and suspended above the fixed part of the MEMS structure.

In some embodiments, a method includes forming a first bonding structure on a substrate and disposing a MEMS structure on the first bonding structure. A comb structure of the MEMS structure is bonded to the substrate by the first bonding structure. The method further includes forming a second bonding structure on a frame structure of the MEMS structure and disposing at least a photonic device on the second bonding structure. The photonic device is bonded to the frame structure by the second bonding structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a micro-electro-mechanical systems (MEMS) structure disposed on the substrate, wherein the MEMS structure comprises a comb structure bonded to the substrate and a frame structure coupled to the comb structure; and
a photonic device disposed on the MEMS structure, wherein the photonic device is bonded to the frame structure.

2. The semiconductor package of claim 1, wherein the comb structure is bonded to the substrate by a bonding structure.

3. The semiconductor package of claim 1, wherein the photonic device is bonded to the frame structure by a bonding structure.

4. The semiconductor package of claim 1, further comprising an interposer disposed between the MEMS structure and the substrate,

5. The semiconductor package of claim 4, wherein the comb structure is bonded to the interposer by a bonding structure.

6. The semiconductor package of claim 1, wherein the photonic device comprises a laser emitter, a transmitter, a receiver, and an optical fiber.

7. The semiconductor package of claim 1, wherein the photonic device comprises a silicon photonic chip.

8. The semiconductor package of claim 1, wherein the MEMS structure further comprises an additional frame structure bonded to substrate and electrically connected to the frame structure.

9. The semiconductor package of claim 1, further comprising a cooling agent surrounding the photonic device.

10. A semiconductor structure, comprising:
a substrate;
a micro-electro-mechanical systems (MEMS) structure disposed on the substrate, wherein the MEMS structure comprises a fixed part bonded to the substrate and a movable part surrounding the fixed part and supported by the fixed part;
a photonic structure bonded to the movable part of the MEMS structure and suspended above the fixed part of the MEMS structure.

11. The semiconductor structure of claim 10, wherein the fixed part of the MEMS structure is bonded to the substrate by a bonding structure.

12. The semiconductor structure of claim 10, wherein the photonic structure is bonded to the movable part of the MEMS structure by a bonding structure.

13. The semiconductor structure of claim 10, further comprising an interposer disposed between the MEMS structure and the substrate,

14. The semiconductor structure of claim 13, wherein the fixed part of the MEMS structure is bonded to the interposer by a bonding structure.

15. The semiconductor structure of claim 10, wherein the photonic structure comprises at least one of a laser emitter, a transmitter, a receiver, and an optical fiber.

16. The semiconductor structure of claim 10, further comprising a cooling agent surrounding the photonic structure.

17. A method, comprising:
forming a first bonding structure on a substrate;
disposing a MEMS structure on the first bonding structure, wherein a comb structure of the MEMS structure is bonded to the substrate by the first bonding structure;
forming a second bonding structure on a frame structure of the MEMS structure; and
disposing at least a photonic device on the second bonding structure, wherein the photonic device is bonded to the frame structure by the second bonding structure.

18. The method of claim 17, wherein forming the first bonding structure on the substrate comprises:
forming a patterning layer on the substrate, wherein the patterning layer comprises an opening exposing the substrate;
depositing a conductive adhesive material in the opening; and
removing the patterning layer.

19. The method of claim 17, further comprising forming an interposer on the substrate, wherein the MEMS structure is bonded to the interposer.

20. The method of claim 17, further comprising surrounding the photonic device in a cooling agent.
